(19) United States
(12) Patent Application Publication
(10) Pub. No.: US 2025/0244260 A1
(43) Pub. Date: Jul. 31, 2025

(54) DETERIORATION DISCRIMINATING DEVICE AND DETERIORATION DISCRIMINATING METHOD

(71) Applicant: Mitsubishi Electric Corporation, Chiyoda, ku, Tokyo (JP)

(72) Inventor: Kenta KANEKO, Chiyoda-ku, Tokyo (JP)

(73) Assignee: Mitsubishi Electric Corporation, Chiyoda-ku, Tokyo (JP)

(21) Appl. No.: 18/701,066

(22) PCT Filed: Dec. 2, 2021
(86) PCT No.: PCT/JP2021/044291

§ 371 Date: Apr. 12, 2024

(51) Int. Cl. G01N 22/02; B60L 3/00; G01M 17/08

(52) U.S. Cl. CPC G01N 22/02; B60L 3/0061; G01M 17/08; B60L 2200/26

(57) ABSTRACT

The degradation determining apparatus includes an antenna and a degradation determiner. The antenna receives an electromagnetic wave in the microwave frequency band emitted due to partial discharge occurring in an insulating member included in a motor, and generate a reception signal. The degradation determiner determines, based on compliance or noncompliance of the reception signal with a standard, whether any degradation occurs in the insulating member.

### TECHNICAL FIELD

The present disclosure relates to a degradation determining apparatus and a degradation determining method.

### BACKGROUND ART

A typical motor includes a rotor including a rotor core and rotor conductors disposed in the slots on the outer periphery of the rotor core or a permanent magnet, and a stator including a stator core and stator coils disposed in the slots on the inner periphery of the stator core. The motor also includes insulating members that insulate the stator core from the stator coils. When these insulating members are degraded, the motor may cause a short circuit therein or aground fault to the outside of the motor. The insulating members are thus preferably inspected at regular intervals regarding the level of degradation.

Motors installed in railway vehicles have large sizes and attached to bogies under the floors of vehicle bodies. These motors require a complicated maintenance process involving detachment of the motors from the bogies and disassembly of the motors. This fact prevents the motors from being frequently inspected to determine whether any degradation occurs in the insulating members of the motors. This problem requires a solution for determining the existence or absence of a degradation in the insulating members without disassembling the motors. An exemplary apparatus for determining the existence or absence of a degradation in the insulating members is disclosed in Patent Literature 1.

### CITATION LIST

### Patent Literature

Patent Literature 1: Unexamined Japanese Patent Application Publication No. 2020-20611

### SUMMARY OF INVENTION

### Technical Problem

The control apparatus disclosed in Patent Literature 1 determines whether any degradation occurs in insulating members included in a motor, on the basis of the values of currents flowing in the motor. The currents flowing in the motor contain harmonic components resulting from switching operations of the switching elements of a power conversion apparatus that feeds electric power to the motor. These harmonic components make it difficult to determine the existence or absence of a degradation in the insulating members of the motor with high accuracy on the basis of the values of currents flowing in the motor.

An objective of the present disclosure, which has been accomplished in view of the above situations, is to provide a degradation determining apparatus and a degradation determining method for determining, with high accuracy, whether any degradation occurs in the insulating members of the motor.

### Solution to Problem

In order to achieve the above objective, a degradation determining apparatus according to the present disclosure includes an antenna and a degradation determiner. The antenna receives an electromagnetic wave in a microwave frequency band emitted due to partial discharge occurring in an insulating member included in a motor, and generate a reception signal. The degradation determiner determines, based on compliance or noncompliance of the reception signal with a standard, whether any degradation occurs in the insulating member.

### Advantageous Effects of Invention

The degradation determining apparatus according to the present disclosure determines whether any degradation occurs in the insulating member, on the basis of compliance or noncompliance of the reception signal with the standard, which is generated from the electromagnetic wave emitted due to the partial discharge occurring in the insulating member of the motor. The reception signal is not affected by harmonic component resulting from a switching operation of a switching element of a power conversion apparatus that feeds electric power to the motor. The degradation determining apparatus can therefore determine, with high accuracy, whether any degradation occurs in the insulating member.

### BRIEF DESCRIPTION OF DRAWINGS

FIG. 1 illustrates a railway vehicle provided with a degradation determining apparatus according to Embodiment 1;

FIG. 2 illustrates exemplary positions of antennas included in the degradation determining apparatus according to Embodiment 1;

FIG. 3 is a block diagram illustrating the degradation determining apparatus according to Embodiment 1;

FIG. 4 illustrates a hardware configuration of the degradation determining apparatus according to Embodiment 1;

FIG. 5 is a flowchart illustrating exemplary steps of a degradation determining process executed by the degradation determining apparatus according to Embodiment 1;

FIG. 6 illustrates an example of phase characteristics of signal intensities in Embodiment 1;

FIG. 7 illustrates another example of phase characteristics of signal intensities in Embodiment 1;

FIG. 8 illustrates another example of phase characteristics of signal intensities in Embodiment 1;

FIG. 9 illustrates another example of phase characteristics of signal intensities in Embodiment 1;

FIG. 10 illustrates another example of phase characteristics of signal intensities in Embodiment 1;

FIG. 11 illustrates another example of phase characteristics of signal intensities in Embodiment 1;

FIG. 12 illustrates exemplary positions of antennas included in a degradation determining apparatus according to Embodiment 2;

FIG. 13 illustrates the exemplary positions of the antennas included in the degradation determining apparatus according to Embodiment 2;

FIG. 14 is a block diagram illustrating a degradation determining apparatus according to Embodiment 3; and

FIG. 15 illustrates a modification of a hardware configuration of the degradation determining apparatus according to the embodiments.

### DESCRIPTION OF EMBODIMENTS

A degradation determining apparatus and a degradation determining method according to the embodiment are described in detail below with reference to the accompanying drawings. In the drawings, the components identical or corresponding to each other are provided with the same reference symbol.

### Embodiment 1

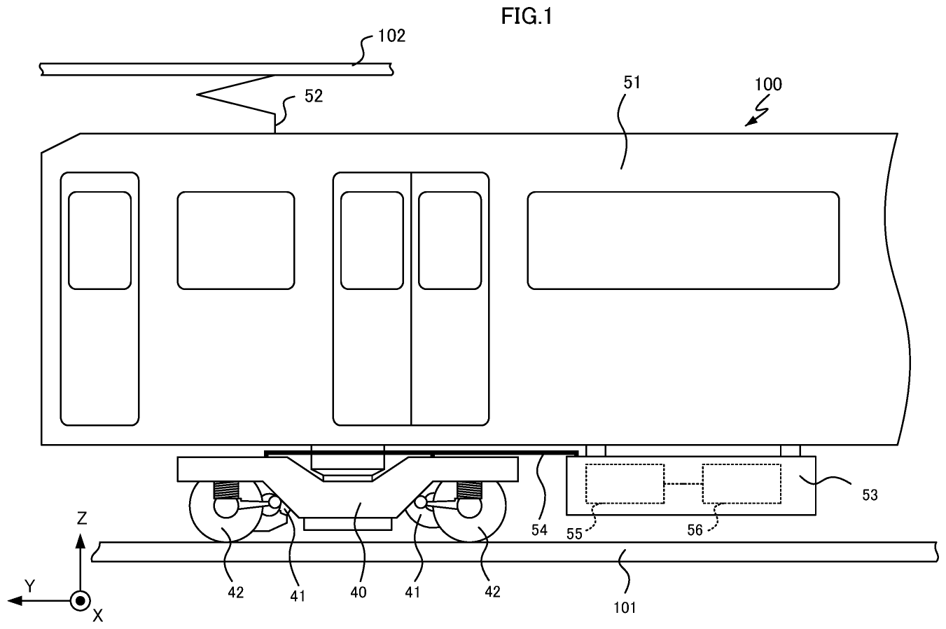

The description of Embodiment 1 is directed to a degradation determining apparatus that determines whether any degradation occurs in insulating members included in a motor driven by electric power fed from a power conversion apparatus. As illustrated in FIG. 1, a railway vehicle 100 includes one or more vehicle bodies 51, bogies 40 that can travel on rails 101 and support the vehicle bodies 51, and a current collector 52 that acquires electric power fed from a substation, which is not illustrated, via a power supply line 102. The X axis in FIG. 1 indicates the width direction of the vehicle bodies 51. The Y axis indicates the traveling direction of the railway vehicle 100. The Z axis is orthogonal to both of the X and Y axes. The Z axis indicates the vertical direction while the railway vehicle 100 is horizontally oriented.

At least one of the vehicle bodies 51 is a motor car. FIG. 1 illustrates the vehicle body 51 serving as a motor car. Each of the vehicle bodies 51 is provided with two bogies 40. FIG. 1 illustrates one of the two bogies 40 alone. The current collector is a pantograph that acquires electric power via an overhead wire corresponding to the power supply line 102, or a contact shoe that acquires electric power via a third rail corresponding to the power supply line 102, for example.

The railway vehicle 100 further includes a power conversion apparatus 53 that is installed under the floor of the vehicle body 51 serving as a motor car and converts electric power acquired by the current collector 52 and outputs the converted electric power, and one or more motors 41 mounted on the bogies 40 and driven by the electric power output from the power conversion apparatus 53. In Embodiment 1, one bogie 40 is provided with two motors 41. The power conversion apparatus 53 is connected to the individual motors 41 with electric wires 54. The electric wires 54 allow electric power to be fed from the power conversion apparatus 53 to the individual motors 41.

In Embodiment 1, the railway vehicle 100 is of a DC feeding system. The power conversion apparatus 53 in this case includes an inverter 55 that converts DC power acquired by the current collector 52 into three-phase AC power and feeds the converted three-phase AC power to the individual motors 41, and an inverter controller that controls the inverter 55. In Embodiment 1, the motors 41 are each a three-phase motor and driven by the three-phase AC power fed from the inverter 55 of the power conversion apparatus 53.

Each of the motors 41 has a rotatably supported shaft, a rotor including a rotor core and rotor conductors disposed in the slots on the outer periphery of the rotor core or a permanent magnet, and a stator including a stator core and stator coils disposed in the slots on the inner periphery of the stator core, although these specific components of the motor 41 are not illustrated. The motor 41 also has an insulating member that insulates the stator core from the stator coils, and insulating members that insulate the mutually adjacent stator coils from each other.

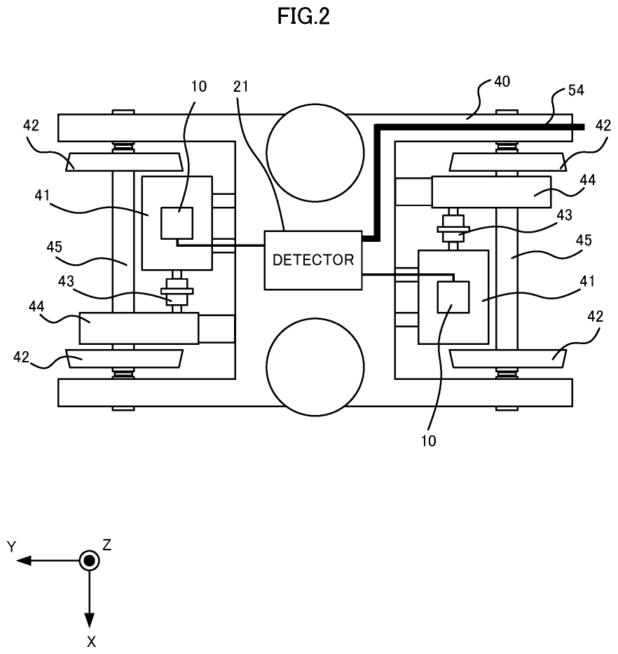

As illustrated in FIG. 2, which is a top view of one of the bogies 40 when viewed in the vertical direction, the bogie 40 has two units each including a joint 43 coupled to the shaft of the corresponding motor 41, a gear mechanism 44 that provides an axle 45 with the torque transmitted from the motor 41 via the joint 43, the axle 45, and wheels 42 fixed to both ends of the axle 45. When each of the motors 41 is driven, the shaft of the motor 41 rotates and transmits its torque to the axle 45 via the joint 43 and the gear mechanism 44. The axle 45 rotates and thus causes the wheels 42 fixed to both ends of the axle 45 to rotate, thereby yielding a propulsion of the railway vehicle 100.

The inverter 55 of the power conversion apparatus 53 illustrated in FIG. 1 has an input terminal that receives a high voltage applied from the current collector 52. The high voltage of DC indicates a voltage in a range of at least 400 V and at most 3,000 V, for example. In the case of the inverter 55 subject to pulse width modulation (PWM) control of the inverter controller 56, the inverter 55 outputs high pulse voltage, which is applied to each of the stator coils of the motors 41, in specific, the U-phase, V-phase, and W-phase coils.

The pulse voltage contains a high surge voltage superimposed thereon, which is instantaneously generated at the rise of the pulse voltage. The surge voltage increases in accordance with the elongation of the electric wires 54. The pulse voltage containing an increased surge voltage superimposed thereon, when applied to the motors 41, cause partial discharge in the insulating members of the motors 41. In detail, partial discharge occurs in some components of each motor 41, which include the insulating member that insulates the stator core from the stator coils, and the insulating members that insulate the mutually adjacent stator coils from each other.

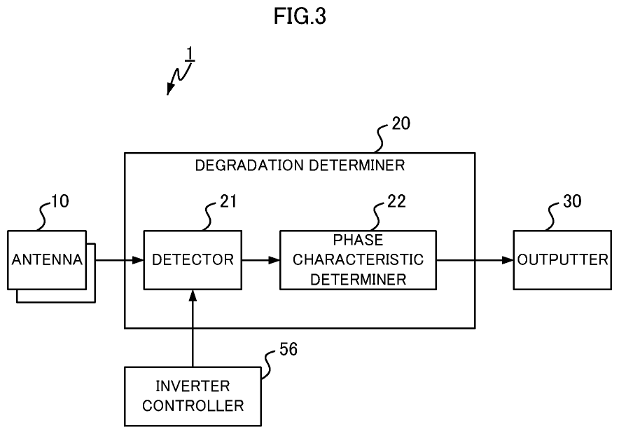

The partial discharge induces emission of electromagnetic waves in the microwave frequency band, in specific, electromagnetic waves having a frequency of at least 300 MHz and at most 300 GHz. If any degradation occurs in the insulating members, the electromagnetic waves in the microwave frequency band generated due to partial discharge have an increased amplitude. In view of this phenomenon, a degradation determining apparatus 1 according to Embodiment 1 illustrated in FIG. 3 determines whether any degradation occurs in the insulating members on the basis of the electromagnetic waves in the microwave frequency band generated due to partial discharge.

The degradation determining apparatus 1 includes one or more antennas 10 that receive the electromagnetic waves in the microwave frequency band emitted due to partial discharge and generate reception signals, and a degradation determiner 20 that determines whether any degradation occurs in the motors 41 on the basis of the amplitudes of the reception signals generated by the antennas 10 or the phase characteristics of signal intensities of the reception signals.

The antennas 10 receive electromagnetic waves in the microwave frequency band. In Embodiment 1, the antennas 10 are planar antennas each oriented such that the surface of the antenna 10 provided with antenna elements faces the corresponding motor 41. The antennas 10 are preferably disposed adjacent to the motors 41. In Embodiment 1, as illustrated in FIG. 2, the antennas 10, such as microstrip antennas, are each mounted on the vertical top of the outer periphery of a frame included in the corresponding motor 41. In detail, each antenna 10 is preferably disposed adjacent to the stator coils of the stator included in the corresponding motor 41. For example, the antenna 10 is preferably adjacent to the U-phase coils in which a U-phase current flows, among the stator coils.

As illustrated in FIG. 3, the degradation determiner 20 acquires reception signals from the antennas 10, and determines whether any degradation occurs in the insulating members of the motors 41 corresponding to the respective antennas 10. In detail, the degradation determiner 20 determines whether any degradation occurs in the insulating members of the motors 41, on the basis of compliance or noncompliance of the reception signals with a standard. For example, the degradation determiner 20 determines whether any degradation occurs in the insulating members of the motors 41, on the basis of the phase characteristics of the reception signals relative to the phase voltage of the motors 41. In Embodiment 1, the degradation determiner 20 determines the existence or absence of a degradation in the insulating members of the motors 41, on the basis of whether the phase characteristics of signal intensities of the reception signals match any of the predetermined phase characteristic patterns. The degradation determiner 20 includes a detector 21 that measures signal intensities of the reception signals in the individual phases, and a phase characteristic determiner 22 that determines whether any degradation occurs in the insulating members of the respective motors 41, on the basis of the phase characteristics of signal intensities of the corresponding reception signals.

The detector 21 is preferably disposed adjacent to the antennas 10 as illustrated in FIG. 2, in view of the fact that the noise to be superimposed on a reception signal increases in accordance with the elongation of the distance between the antennas and the detector 21. In Embodiment 1, a single detector 21 is provided for the two antennas 10. The detector 21 is mounted on the upper surface of the bogie 40. The detector 21 illustrated in FIG. 3 receives the reception signals from the antennas 10, and executes signal processing, such as denoising, analog-to-digital (A-D) conversion, and detection, on the received reception signals. The detector 21 then measures signal intensities of the reception signals after the signal processing, at predetermined detection timings having intervals of ten milliseconds, for example, for a predetermined detection period of five seconds, for example.

The detector 21 then associates the measured signal intensities with the phases, relative to the phase of the pulse voltage applied to the motors 41, in specific, the phase of U-phase voltage of the motors 41. In an exemplary case where the antennas 10 are located adjacent to the U-phase coils, the detector 21 acquires U-phase voltage command value from the inverter controller 56, generates pieces of detection data by associating the measured signal intensities with the phases relative to the 0-degree phase defined at the rise of the U-phase voltage command value, and outputs the generated pieces of detection data to the phase characteristic determiner 22.

The phase characteristic determiner 22 determines whether any degradation occurs in the insulating members of the motors 41, on the basis of the phase characteristics of the reception signals indicated by the pieces of detection data acquired from the detector 21. The phase characteristic determiner 22 preferably also identifies the type of the degradation in the insulating members by comparing the phase characteristics of the reception signals with the phase characteristic patterns associated with the respective types of degradation in the insulating members. The phase characteristic determiner 22 then transmits, to an outputter 30, a result of determination indicating the existence or absence of a degradation in the insulating members, or a result of determination indicating the existence or absence of a degradation in the insulating members and the type of the degradation in the insulating members.

The degradation determiner 20 except for the detector 21, that is, the phase characteristic determiner 22 is installed in a cab, for example. The detector 21 is connected to the phase characteristic determiner 22 with a transmission line extending through the railway vehicle 100.

The outputter 30 is a display installed in the cab, for example, and outputs the result of determination transmitted from the phase characteristic determiner 22. In detail, the outputter 30 causes the result of determination from the phase characteristic determiner 22 to be displayed on a screen.

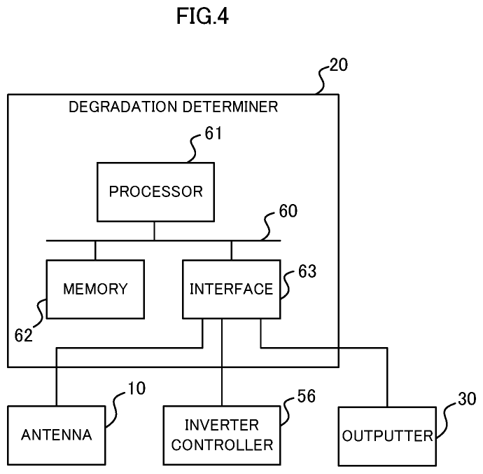

FIG. 4 illustrates a hardware configuration of the degradation determiner 20 of the degradation determining apparatus 1, which has the above-described configuration. The degradation determiner 20 includes a processor 61, a memory 62, and an interface 63. The processor 61, the memory 62, and the interface 63 are connected to each other via buses 60. The functions of the detector 21 and the phase characteristic determiner are performed by software, firmware, or a combination of software and firmware. The software and firmware are described in the form of programs and stored in the memory 62. The processor 61 reads and executes the programs stored in the memory 62, and thus achieves the above-described functions of the components. That is, the memory 62 stores the programs for executing the processes of the detector 21 and the phase characteristic determiner 22.

Examples of the memory 62 include non-volatile or volatile semiconductor memories, such as random access memory (RAM), read-only memory (ROM), flash memory, erasable programmable read-only memory (EPROM), and electrically erasable and programmable read-only memory (EEPROM), magnetic disks, flexible disks, optical disks, compact discs, mini discs, and digital versatile discs (DVDs).

The degradation determining apparatus 1 having the above-described configuration executes operations described below.

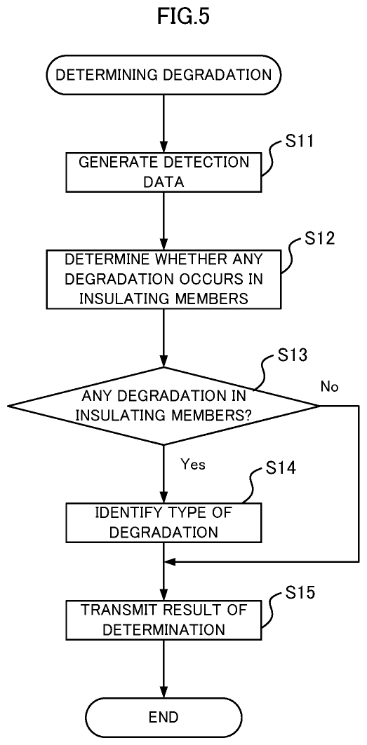

The degradation determining apparatus 1 initiates a degradation determining process illustrated in FIG. 5, in response to the activation of the inverter 55 of the power conversion apparatus 53. For example, the degradation determining apparatus 1 acquires the U-phase voltage command value from the inverter controller 56 and detects a rise in the U-phase voltage command value, and then initiates the degradation determining process.

The detector 21 executes signal processing on the reception signals acquired from the antennas 10, measures signal intensities, and generates pieces of detection data by associating the measured signal intensities with the phases indicated by the U-phase voltage command value acquired from the inverter controller 56 (Step S11). The phase characteristic determiner 22 determines whether any degradation occurs in the insulating members of the motors 41, on the basis of the phase characteristics of signal intensities of the reception signals indicated by the pieces of detection data generated in Step S11, in specific, on the basis of variations in the signal intensities of the reception signals depending on the phases (Step S12).

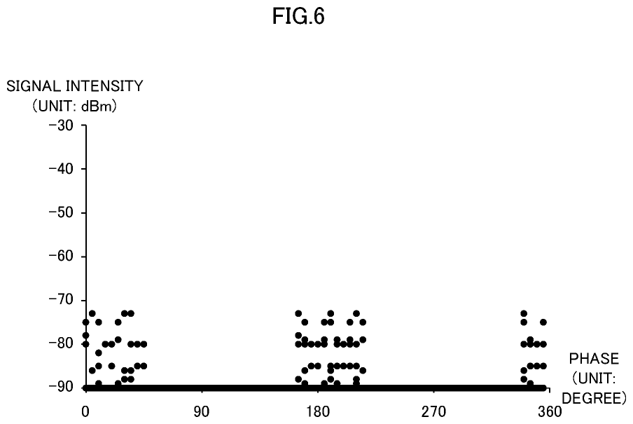

The pieces of detection data generated in the case of no degradation in the insulating members of the motors 41, when being plotted in the X and Y coordinates, indicate the phase characteristics of signal intensities of the reception signals, like those illustrated in FIG. 6, for example. The horizontal axis in FIG. 6 indicates a phase (unit: degree), and the vertical axis indicates a signal intensity (unit: dBm). In an exemplary case where the reception signals output from the antennas 10 have electric powers of at least 10⁻⁹ mW and at most 10⁻³ mW, the signal intensities resulting from conversion of the electric powers are at least −90 dBm and at most −30 dBm, as illustrated in FIG. 6.

In Embodiment 1, when the phase characteristic determiner 22 deems the phase characteristics of signal intensities of the reception signals to have features similar to those of the phase characteristic pattern illustrated in FIG. 6, the phase characteristic determiner 22 determines that no degradation occurs in the insulating members. In specific, when the phases of the pieces of detection data indicating signal intensities higher than the lower limit, for example, higher than −90 dBm are in the vicinity of 0, 180, or 360 degrees and when the signal intensities are within a normal intensity range, for example, equal to or lower than −70 dBm, like those in FIG. 6, the phase characteristic determiner 22 determines that no degradation occurs in the insulating members.

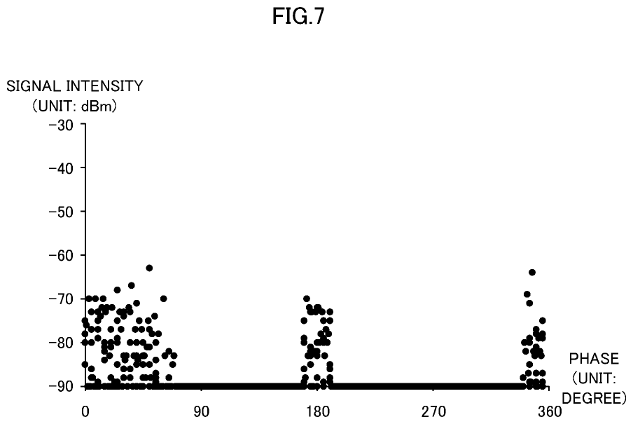

The phase characteristic determiner 22 preliminarily retains the pieces of detection data obtained during driving of the motors 41 in the case of no degradation in the insulating members of the motors 41, in the form of phase characteristic patterns in normal states. Also, the phase characteristic determiner 22 preliminarily retains the pieces of detection data obtained during driving of the motors 41 in the case of some degradation in the insulating members of the motors 41, in the form of phase characteristic patterns in degraded states. Examples of these phase characteristic patterns include the phase characteristic pattern in a normal state illustrated in FIG. 6, and the phase characteristic patterns in degraded states illustrated in FIGS. 7 to 10.

The phase characteristic determiner 22 preliminarily learns the phase characteristic patterns in the normal states and the phase characteristic patterns in the degraded states, by machine learning. For example, the phase characteristic determiner causes a memory, which is not illustrated, to store the pieces of detection data obtained during driving of the motors 41 in the case of no degradation in the insulating members of the motors 41, and the types of degradation in the insulating members of the motors 41, in specific, the pieces of detection data obtained during driving of the motors 41 in the case of some degradation in the insulating members for each of the types of degradation in the insulating members. In detail, each of the pieces of detection data is associated with a label indicating the existence or absence of a degradation in the insulating members and a type of the degradation in the insulating members, and is then stored into the memory in the form of a piece of learning data. The types of degradation in the insulating members are preliminarily determined for classification of degradations in the insulating members depending on causes of the degradations in the insulating members, and the positions of the degraded insulating members, for example.

The phase characteristic determiner 22 learns phase characteristic patterns using such pieces of learning data. The machine learning uses a neural network algorithm, for example. Using the pieces of learning data, the phase characteristic determiner 22 extracts the variations in the signal intensities in the individual phases, in specific, the features of the signal intensities, such as dispersion, average, or maximum value, and recognizes the phase characteristic pattern, depending on the existence or absence of a degradation in the insulating members, and the type of the degradation in the insulating members in the case of some degradation in the insulating members. The phase characteristic determiner 22 identifies and stores the phase characteristic patterns in the normal states and the phase characteristic patterns associated with the individual types of degradation in the insulating members. The phase characteristic determiner 22 then determines whether any degradation occurs in the insulating members and identifies the type of the degradation in the insulating members, on the basis of the phase characteristic patterns in the normal states and the phase characteristic patterns associated with the individual types of degradation in the insulating members.

The lower limit is defined depending on the electric powers of the reception signals, as described above. The phase in the vicinity of 0 degree means the phase in a range of at least 0 degree and at most 10 degrees, for example. The phase in the vicinity of 180 degrees means the phase in a range of at least 170 degrees and at most 190 degrees, for example. The phase in the vicinity of 360 degrees means the phase in a range of at least 350 degrees and lower than 360 degrees, for example. The normal intensity range is defined depending on the possible signal intensities of the reception signals in the case of no degradation in the insulating members of the motors 41, for example.

In detail, the phase characteristic determiner 22 counts the number of pieces of detection data indicating signal intensities higher than the lower limit and indicating phases in the vicinity of 0, 180, or 360 degrees. When the counted number is equal to or larger than a first threshold, the phase characteristic determiner 22 deems the phases of the pieces of detection data indicating signal intensities higher than the lower limit to be concentrated in the vicinity of 0, 180, or 360 degrees, and determines that no degradation occurs in the insulating members. The first threshold is calculated by multiplying the total number of pieces of detection data by 0.5, for example. In other words, the first threshold is calculated by multiplying a value, which is the quotient of the detection period of the detector 21 and the length of the intervals between the detection timings, by 0.5.

Referring back to FIG. 5, when the phase characteristic determiner 22 determines that no degradation occurs in the insulating members (Step S13; No), the phase characteristic determiner 22 skips Step S14. The phase characteristic determiner then transmits a result of determination indicating no degradation in the insulating members, to the outputter 30 (Step S15).

In contrast, when the phase characteristic determiner 22 deems the phase characteristics of the signal intensities not to have features similar to those of the phase characteristic pattern illustrated in FIG. 6 and thus determines that some degradation occurs in the insulating members (Step S13; Yes), the phase characteristic determiner 22 identifies the type of the degradation in the insulating members (Step S14).

In Step S14, the phase characteristic determiner 22 compares the phase characteristics of signal intensities of the reception signals with the phase characteristic patterns associated with the types of degradation in the insulating members, and thereby identifies the type of the degradation in the insulating members.

For example, the phase characteristic determiner 22 retains the phase characteristic pattern illustrated in FIG. 7, in the form of the phase characteristic pattern associated with dirt in the insulating members at the coil ends of the stator coils. When the phase characteristic determiner 22 deems the phase characteristics of signal intensities of the reception signals to have features similar to those of the phase characteristic pattern illustrated in FIG. 7, the phase characteristic determiner 22 determines that the insulating members at the coil ends of the stator coils have dirt. In detail, when the phases of the pieces of detection data indicating signal intensities higher than the lower limit are concentrated in the vicinities of 0, 180, and 360 degrees but the signal intensities indicated by some of the pieces of detection data exceed the normal intensity range, as illustrated in FIG. 7, the phase characteristic determiner 22 determines that the insulating members at the coil ends of the stator coils have dirt.

For example, the phase characteristic determiner 22 counts the number of pieces of detection data indicating signal intensities higher than the lower limit and indicating phases in the vicinity of 0, 180, or 360 degrees, as in the step of comparison with the phase characteristic pattern illustrated in FIG. 6. The phase characteristic determiner 22 also counts the number of pieces of detection data indicating signal intensities higher than the normal intensity range. When the counted number of pieces of detection data indicating signal intensities higher than the normal intensity range is equal to or larger than a second threshold, the phase characteristic determiner 22 deems the signal intensities indicated by some of the pieces of detection data to be higher than the normal intensity range. The second threshold is defined to avoid erroneous determination based on abnormal values. The second threshold is calculated by multiplying the total number of pieces of detection data by 0.1, for example. In other words, the second threshold is calculated by multiplying a value, which is the quotient of the detection period of the detector 21 and the length of the intervals between the detection timings, by 0.1.

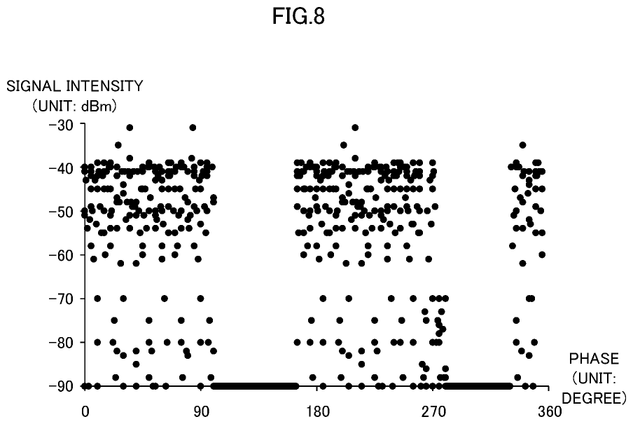

For another example, the phase characteristic determiner 22 retains the phase characteristic pattern illustrated in FIG. 8, in the form of the phase characteristic pattern associated with a degradation in the insulating members around thermocouples attached to the stator coils. The thermocouples are disposed in the slots of the stator core for accommodating the stator coils, at positions between the stator coils and the stator core, in order to measure temperatures of the stator coils. When the phase characteristic determiner 22 deems the phase characteristics of signal intensities of the reception signals to have features similar to those of the phase characteristic pattern illustrated in FIG. 8, the phase characteristic determiner 22 determines that some degradation occurs in the insulating members around the thermocouples attached to the stator coils. In detail, when the phases of the pieces of detection data indicating signal intensities higher than the normal intensity range are concentrated in a range of at least 0 degree and at most 90 degrees or a range of at least 180 degrees and at most 270 degrees, as illustrated in FIG. 8, the phase characteristic determiner 22 determines that some degradation occurs in the insulating members around the thermocouples attached to the stator coils.

For example, the phase characteristic determiner 22 counts the number of pieces of detection data indicating signal intensities higher than the normal intensity range and indicating phases in a range of at least 0 degree and at most 90 degrees or a range of at least 180 degrees and at most 270 degrees. When the counted number is equal to or larger than the first threshold, the phase characteristic determiner 22 deems the phases of the pieces of detection data indicating signal intensities higher than the normal intensity range to be concentrated in a range of at least 0 degree and at most 90 degrees or a range of at least 180 degrees and at most 270 degrees, and determines that some degradation occurs in the insulating members around the thermocouples attached to the stator coils.

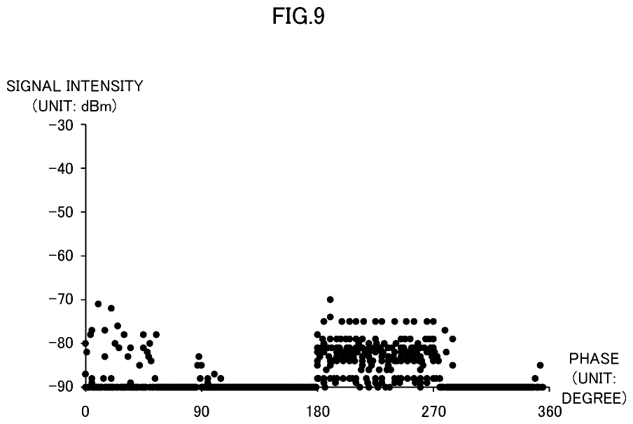

For another example, the phase characteristic determiner 22 retains the phase characteristic pattern illustrated in FIG. 9, in the form of the phase characteristic pattern associated with separation of the insulating members around the electrodes of the stator coils. When the phase characteristic determiner 22 deems the phase characteristics of the signal intensities to have features similar to those of the phase characteristic pattern illustrated in FIG. 9, the phase characteristic determiner 22 determines that separation occurs in the insulating members around the electrodes of the stator coils. In detail, when the phases of the pieces of detection data indicating signal intensities higher than the lower limit are concentrated in a range of at least 180 degrees and at most 270 degrees, as illustrated in FIG. 9, the phase characteristic determiner 22 determines that separation occurs in the insulating members around the electrodes of the stator coils.

For example, the phase characteristic determiner 22 counts the number of pieces of detection data indicating signal intensities higher than the lower limit and indicating phases in a range of at least 180 degrees and at most 270 degrees. When the counted number is equal to or larger than a third threshold, the phase characteristic determiner 22 deems the phases of the pieces of detection data indicating signal intensities higher than the normal intensity range to be concentrated in a range of at least degrees and at most 270 degrees, and determines that separation occurs in the insulating members around the electrodes of the stator coils. The third threshold is calculated by multiplying the total number of pieces of detection data by 0.8, for example. In other words, the third threshold is calculated by multiplying a value, which is the quotient of the detection period of the detector 21 and the length of the intervals between the detection timings, by 0.8.

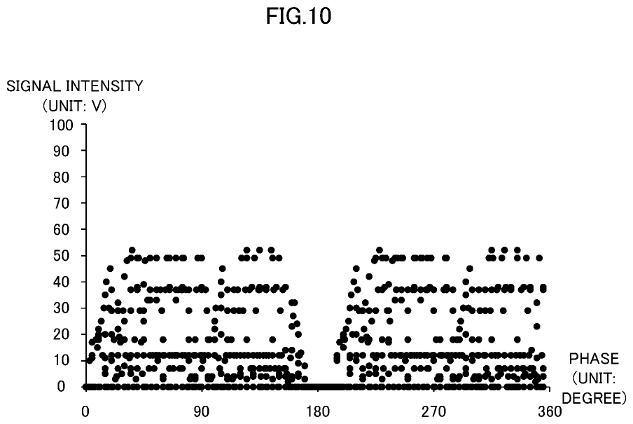

For another example, the phase characteristic determiner 22 retains the phase characteristic pattern illustrated in FIG. 10, in the form of the phase characteristic pattern associated with some degradation in the insulating members between mutually adjacent stator coils. When the phase characteristic determiner 22 deems the phase characteristics of the signal intensities to have features similar to those of the phase characteristic pattern illustrated in FIG. 10, the phase characteristic determiner 22 determines that some degradation occurs in the insulating members between mutually adjacent stator coils. The horizontal axis in FIG. 10 represents a phase (unit: degree), and the vertical axis represents a signal intensity (unit: V). The value of 0 V on the vertical axis in FIG. 10 corresponds to the value of −90 dBm in FIG. 6. The value of 100 V on the vertical axis in FIG. 10 corresponds to the value of −30 dBm in FIG. 6. When the phases of the pieces of detection data indicating signal intensities higher than the lower limit, for example, higher than 0 V are concentrated in ranges other than the vicinity of 180 degrees, as illustrated in FIG. 10, the phase characteristic determiner 22 determines that some degradation occurs in the insulating members between mutually adjacent stator coils.

In detail, the phase characteristic determiner 22 counts the number of pieces of detection data indicating signal intensities higher than the lower limit and indicating phases in a range of at least 0 degree and at most 170 degrees or a range of at least 190 degrees and lower than 360 degrees. When the counted number is equal to or larger than the third threshold, the phase characteristic determiner 22 deems the phases of the pieces of detection data indicating signal intensities higher than the lower limit to be concentrated in ranges other than the vicinity of 180 degrees, and determines that some degradation occurs in the insulating members between mutually adjacent stator coils.

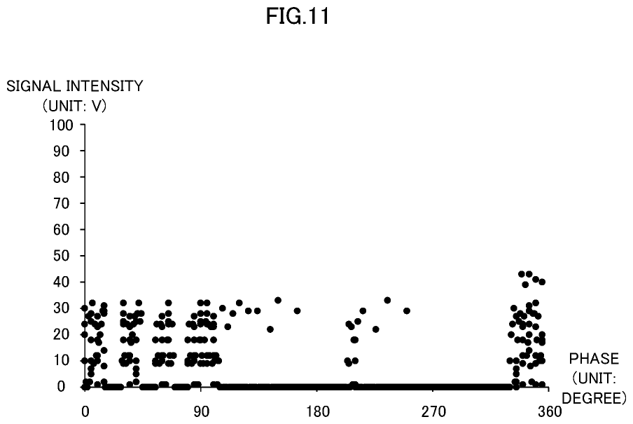

For another example, when the phase characteristic determiner 22 deems the phase characteristics of the signal intensities to have features similar to those of the phase characteristic pattern illustrated in FIG. 11, the phase characteristic determiner 22 determines that a metal contaminant having a needle shape adhering at any of the coil ends of the stator coils causes some degradation in the insulating members at the coil ends. In detail, when the phases of the pieces of detection data indicating signal intensities higher than the lower limit are concentrated in a range of at least 0 degree and at most 90 degrees or a range of at least 330 degrees and lower than 360 degrees, as illustrated in FIG. 11, the phase characteristic determiner 22 determines that a metal contaminant having a needle shape adhering at any of the coil ends of the stator coils causes some degradation in the insulating members at the coil ends.

For example, the phase characteristic determiner 22 counts the number of pieces of detection data indicating signal intensities higher than the lower limit and indicating phases in a range of at least 0 degree and at most 90 degrees or a range of at least 330 degrees and lower than 360 degrees. When the counted number is equal to or larger than the third threshold, the phase characteristic determiner 22 deems the phases of the pieces of detection data indicating signal intensities higher than the lower limit to be concentrated in a range of at least 0 degree and at most 90 degrees and a range of at least degrees and lower than 360 degrees, and determines that a metal contaminant having a needle shape adhering at any of the coil ends of the stator coils causes some degradation in the insulating members at the coil ends.

Referring back to FIG. 5, the phase characteristic determiner 22, which identifies the type of degradation in the insulating members as described above, transmits a result of determination indicating the existence of a degradation in the insulating members and the type of the degradation in the insulating members, to the outputter 30 (Step S15).

After completion of Step S15, the degradation determining apparatus 1 terminates the degradation determining process. The degradation determining apparatus repeats the above-described process until the deactivation of the inverter 55 of the power conversion apparatus 53. For example, when the U-phase voltage command value is stable for at least a certain period, the degradation determining apparatus 1 deems the inverter 55 to be deactivated and stops repetition of the degradation determining process.

As described above, the degradation determining apparatus 1 according to Embodiment 1 determines whether any degradation occurs in the insulating members of the motors 41, on the basis of the phase characteristics of signal intensities of the reception signals generated from electromagnetic waves in the microwave frequency band. The degradation determining apparatus 1 can thus determine the existence or absence of a degradation in the insulating members of the motors 41 with high accuracy, without being affected by harmonic components resulting from switching operations of the switching elements included in the inverter 55 of the power conversion apparatus 53.

In addition, the phase characteristic determiner 22 identifies the type of degradation in the insulating members of the motors 41, on the basis of comparison between the phase characteristics of signal intensities of the reception signals with the phase characteristic patterns associated with the types of degradation in the insulating members, and can thus notify the outputter 30 of the type of the degradation in the insulating members of the motors 41. The identification of the type of degradation in the insulating members allows for a maintenance process suitable for the degradation in the insulating members, leading to an efficient maintenance process of the motors 41.

### Embodiment 2

The antennas 10 and the degradation determining apparatus 1 may be disposed at positions other than those in the above-described examples. The description of Embodiment 2 is directed to antennas 10 and a degradation determining apparatus 1 not installed in the railway vehicle 100.

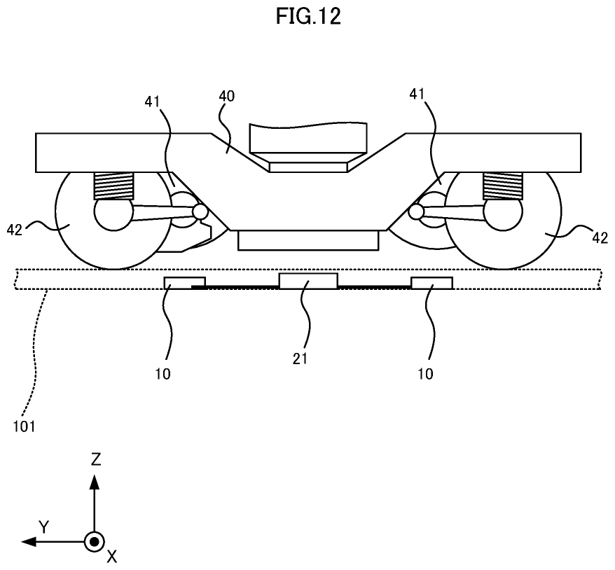

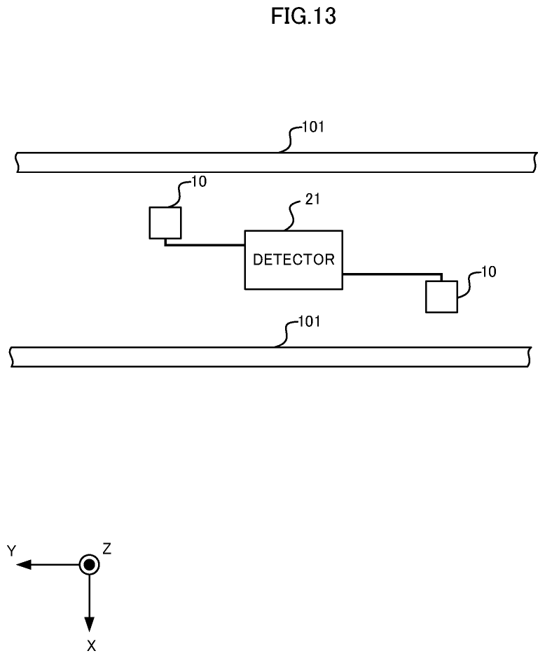

The degradation determining apparatus 1 has the same configuration as that in Embodiment 1. As illustrated in FIGS. 12 and 13, the degradation determining apparatus 1 according to Embodiment 2 includes two antennas 10 disposed between the two rails 101 on which the railway vehicle 100 runs. FIG. 12 illustrates one of the two rails 101 on the positive side in the horizontal axis directions with a dotted line. The two antennas 10 have relative positions determined in accordance with the positions of the two motors 41 in each of the bogies 40. The detector 21 is disposed adjacent to the two antennas 10.

In detail, the antennas 10 are disposed adjacent to the rails 101 in an area, such as station or rail yard, in which the railway vehicle 100 runs at a low velocity, in specific, at a velocity of 10 km/h or lower, for example.

In Embodiment 2, the antennas 10 are planar antennas each disposed between the two rails 101 and oriented such that the surface of the antenna 10 provided with antenna elements faces vertically upward.

The detector 21 acquires the U-phase voltage command value from the inverter controller 56 of the power conversion apparatus 53 installed in the railway vehicle 100, via a communication device installed in the railway vehicle 100. For example, the detector 21 acquires data indicating the U-phase voltage command value from a wireless communication device installed in the railway vehicle 100. The detector 21 then executes signal processing on the reception signals acquired from the antennas 10, and generates pieces of detection data by associating the signal intensities of the reception signals after the signal processing with the phases indicated by the U-phase voltage command value, as in Embodiment 1.

The degradation determiner 20 except for the detector 21, that is, the phase characteristic determiner 22 is disposed in ground equipment installed in the station or rail yard, for example. The degradation determiner 20 determines whether any degradation occurs in the insulating members of the motors 41 on the basis of the pieces of detection data acquired from the detector 21, and transmits a result of determination to the outputter 30, as in Embodiment 1.

The outputter 30 identifies one of the motors 41 determined to have some degradation in the insulating members by the degradation determining apparatus 1, in accordance with running information on the railway vehicle 100 and trainset information on the railway vehicle 100. The outputter 30 then outputs the result of determination and the identified motor 41 in association with each other. In detail, the outputter 30 identifies the motor 41 that is located above the antenna 10 at the timing of the degradation determining process of the degradation determining apparatus 1, on the basis of the running information and the trainset information on the railway vehicle 100 and the necessary period for the degradation determining process of the degradation determining apparatus 1.

As described above, the degradation determining apparatus 1 according to Embodiment 2 determines whether any degradation occurs in the insulating members of the motors 41, on the basis of the phase characteristics of signal intensities of the reception signals generated by the antennas 10 disposed adjacent to the rails 101. The antennas 10 are thus not required to be provided for the individual motors 41, and can therefore simplify the structure for determining the existence or absence of degradation in the insulating members of the motors 41.

### Embodiment 3

Although the degradation determining apparatus 1 according to Embodiment 1 or determines whether any degradation occurs in the insulating members on the basis of the phase characteristics of signal intensities of the reception signals, this determination may be executed on the basis of the signal waveforms of the reception signals. The description of Embodiment 3 is directed to a degradation determining apparatus 2 that determines whether any degradation occurs in the insulating members of the motors 41, on the basis of the signal waveforms of the reception signals.

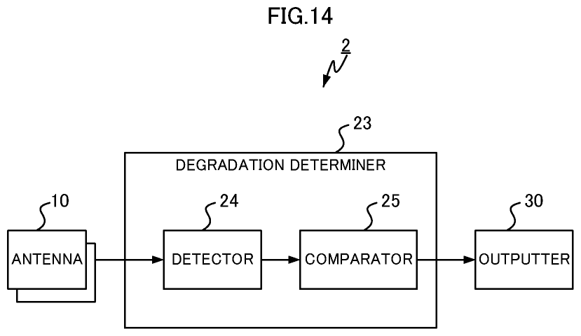

The degradation determining apparatus 2 illustrated in FIG. 14 includes a degradation determiner 23, which includes a detector 24 that measures signal values of the reception signals at sampling timings having intervals of 10 milliseconds, for example, and a comparator 25 that determines whether any degradation occurs in the insulating members of the motors 41 by comparing the signal values of the reception signals with each other. The degradation determiner 23 has a hardware configuration like that of the degradation determiner 20 of the degradation determining apparatus 1 according to Embodiment 1, except for that the degradation determiner 23 is not required to communicate with the inverter controller 56.

The antennas 10 are disposed adjacent to the coils of the same phase. For example, the antennas 10 are disposed adjacent to the U-phase coils of the respective motors 41.

The detector 24 executes signal processing, such as denoising, A-D conversion, and detection, on the individual reception signals received from the antennas associated with the respective motors 41 driven by the electric power fed from the common power conversion apparatus 53. The detector 24 measures signal values of signal waveforms in the time domain at sampling timings regarding the individual reception signals after the signal processing, and outputs the measured signal values to the comparator 25.

The comparator 25 compares the signal values of the reception signals, which are measured by the detector 24. When the signal values have differences smaller than a difference threshold, for example, smaller than 10%, the comparator 25 deems the signal values to be the same. When the signal values are the same, the motors 41 driven by the electric power fed from the common power conversion apparatus can be deemed to be operating in the same manner. The comparator 25 thus determines that no degradation except for degradation with age occurs in the insulating members, for example, no degradation due to adhesion of a contaminant occurs in the insulating members, when the signal values have differences smaller than the difference threshold.

In contrast, when the signal values have differences equal to or larger than the difference threshold, for example, equal to or larger than 10%, the comparator 25 deems the signal values to be different from each other. The different signal values mean that the motors 41 driven by the electric power fed from the common power conversion apparatus 53 are operating in different manners. The comparator 25 thus determines that some degradation except for degradation with age occurs in the insulating members, for example, some degradation due to adhesion of a contaminant occurs in the insulating members, when the signal values have differences equal to or larger than the difference threshold.

Alternatively, the comparator 25 may repeat the comparison between the signal values for a target period of one second, for example. This comparator 25 may determine that some degradation except for degradation with age occurs in the insulating members, when the number of results of comparison, indicating the differences among the signal values equal to or larger than the difference threshold, is equal to or larger than a determination threshold. This modification can avoid erroneous determination of a degradation in the insulating members. The determination threshold is calculated by multiplying a value, which is the quotient of the target period by the length of sampling intervals, by 0.1, for example.

The comparator 25 transmits, to the outputter 30, a result of determination indicating the existence or absence of a degradation in the insulating members, which is based on the above-described comparison between the signal values.

As described above, the degradation determining apparatus 2 according to Embodiment 3 can determine whether any degradation occurs in the insulating members of the motors 41, on the basis of the signal waveforms of the reception signals generated from electromagnetic waves in the microwave frequency band.

The above-described embodiments are not to be construed as limiting the present disclosure. The above-described hardware configuration and flowchart are mere examples and may be arbitrarily varied and modified.

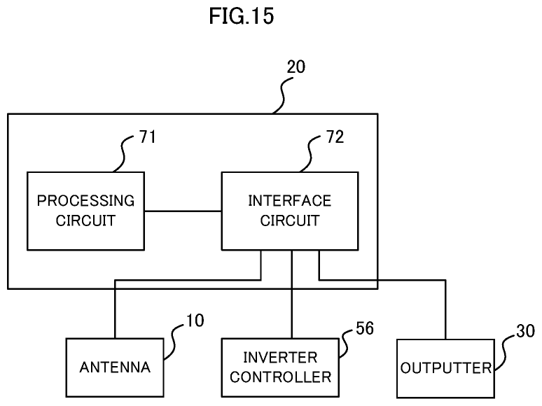

The degradation determiner 20 may be achieved by a processing circuit 71, as illustrated in FIG. 15. The processing circuit 71 in this case is connected to the antennas 10, the inverter controller 56, and the outputter 30 via an interface circuit 72. In the case where the processing circuit 71 is dedicated hardware, the processing circuit is a single circuit, a combined circuit, a programmed processor, a parallel programmed processor, an application specific integrated circuit (ASIC), a field programmable gate array (FPGA), or a combination thereof, for example. The detector 21 and the phase characteristic determiner 22 may be achieved by separate processing circuits 71 or by the same processing circuit 71. The same holds true for the degradation determiner 23.

A part of the functions of the detector 21 and the phase characteristic determiner 22 of the degradation determiner 20 may be performed by dedicated hardware, while another part of the functions may be performed by software or firmware. For example, the detector 21 may be achieved by the processing circuit 71 illustrated in FIG. 15, whereas the phase characteristic determiner 22 may be achieved by programs stored in the memory 62 when the programs are read and executed by the processor 61 illustrated in FIG. 4.

The antennas 10 may be disposed at positions other than those in the above-described examples, provided that the antennas 10 can receive the electromagnetic waves generated due to partial discharge. For example, the antennas 10 may be disposed adjacent to the V-phase coils in which a V-phase current flows among the stator coils, or adjacent to the W-phase coils in which a W-phase current flows among the stator coils. For another example, the antennas 10 may be provided to cables connected to the motors 41. For the motors 41 of a frameless type, the antennas 10 may be mounted on the respective outer peripheries of the stator cores.

The antennas 10 may each be any directional antenna, other than the planar antenna, that can receive the electromagnetic waves emitted due to partial discharge occurring in the insulating members of the target motors 41, and can reduce the interference with the electromagnetic waves emitted from other motors 41.

The detector 21 may provide the phase characteristic determiner 22 with pieces of detection data generated by associating the measured signal intensities with the phases, relative to the phase of the V-phase voltage of the motors 41. Alternatively, the detector 21 may provide the phase characteristic determiner 22 with pieces of detection data generated by associating the measured signal intensities with the phases, relative to the phase of the W-phase voltage of the motors 41.

The phase characteristic determiner 22 may determine whether any degradation occurs in the insulating members of the motors 41, on the basis of the phase characteristics of signal intensities of the reception signals and a history of operation conditions of each of the motors 41. The operation conditions of the motor 41 contain at least any of a running period of the inverter 55, a switching frequency of the inverter 55, a rotational speed of the motor 41, a temperature of the motor 41, and an occupancy rate of the vehicle body 51 supported by the bogie 40 provided with the motor 41.

For example, the phase characteristic determiner 22 may retain multiple phase characteristic patterns in the normal states like that illustrated in FIG. 6, in association with average rotational speeds of the operating motors 41. The phase characteristic determiner 22 may compare the phase characteristics of signal intensities of the reception signals with the phase characteristic pattern associated with the average rotational speed of the operating motors 41, and thus determine whether any degradation occurs in the insulating members of the motors 41.

For another example, the phase characteristic determiner 22 may retain multiple phase characteristic patterns during occurrence of degradation in the insulating members like that illustrated in FIG. 7, in association with average temperatures of the operating motors 41. The phase characteristic determiner 22 may compare the phase characteristics of signal intensities of the reception signals with the phase characteristic pattern associated with the average temperature of the operating motors 41, and thus identify the type of degradation in the insulating members of the motors 41.

The phase characteristic determiner 22 may be achieved in the form of a function of a train information management system. Also, the comparator 25 may be achieved in the form of a function of the train information management system.

The phase characteristic determiner 22 may determine only the existence or absence of a degradation in the insulating members of the motors 41. In this case, the phase characteristic determiner 22 may skip Step S14 in FIG. 5.

Each of the motors 41 may be either of a three-phase induction motor and a three-phase synchronous motor. The motor 41 may be a single-phase motor or a DC motor, other than the three-phase motor, for example. The motor 41 may be an inner-rotor type or outer-rotor type.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to betaken in a limiting sense, and the scope of the invention is defined only by the included claims, along with the full range of equivalents to which such claims are entitled.

### REFERENCE SIGNS LIST

1, 2 Degradation determining apparatus
10 Antenna
20, 23 Degradation determiner
21, 24 Detector
22 Phase characteristic determiner
25 Comparator
30 Outputter
40 Bogie
41 Motor
42 Wheel
43 Joint
44 Gear mechanism
45 Axle
51 Vehicle body
52 Current collector
53 Power conversion apparatus
54 Electric wire
55 Inverter
56 Inverter controller
60 Bus
61 Processor
62 Memory
63 Interface
71 Processing circuit
72 Interface circuit
100 Railway vehicle
101 Rail
102 Power supply line

1. A degradation determining apparatus, comprising:
an antenna to receive an electromagnetic wave in a microwave frequency band emitted due to partial discharge occurring in an insulating member included in a motor, and generate a reception signal; and
degradation determining circuitry to compare a phase characteristic of a signal intensity of the reception signal with a phase characteristic pattern associated with a type of degradation in the insulating member, and determine whether any degradation occurs in the insulating member and identify the type of the degradation in the insulating member including at least one of a cause of the degradation in the insulating member or a position of the degraded insulating member.

2-3. (canceled)

4. The degradation determining apparatus according to claim 1, wherein
the antenna includes a plurality of the antennas being planar antennas each oriented such that a surface of the antenna provided with antenna elements faces a corresponding motor of a plurality of the motors.

5. A degradation determining apparatus, comprising:
a plurality of antennas to receive electromagnetic waves in a microwave frequency band emitted due to partial discharge occurring in insulating members included in a plurality of motors, and generate reception signals, the plurality of antennas being planar antennas each disposed adjacent to a corresponding motor of the plurality of the motors and oriented such that a surface of the antenna provided with antenna elements faces the corresponding motor, the plurality of motors being configured to be fed with electric power from a common power conversion apparatus, and
degradation determining circuitry to determine, based on a difference among signal values of the reception signals generated by the plurality of antennas, whether any degradation occurs in the insulating member.

6. The degradation determining apparatus according to claim 1, wherein the antenna is mounted on an outer surface of a frame of the motor.

7-11. (canceled)

12. The degradation determining apparatus according to claim 5, wherein each of the plurality of antennas is mounted on an outer surface of a frame of the corresponding motor.

13. The degradation determining apparatus according to claim 1, wherein the antenna is mounted on an outer surface of a stator core of the motor.

14. The degradation determining apparatus according to claim 5, wherein each of the plurality of antennas is mounted on an outer surface of a stator core of the corresponding motor.

15. The degradation determining apparatus according to claim 1, wherein
the motor is installed under a floor of a railway vehicle and generates a propulsion of the railway vehicle, and
the antenna is disposed adjacent to the motor under the floor of the railway vehicle.

16. The degradation determining apparatus according to claim 5, wherein
the plurality of motors is installed under a floor of a railway vehicle and generates a propulsion of the railway vehicle, and
each of the plurality of antennas is disposed adjacent to the corresponding motor under the floor of the railway vehicle.

17. The degradation determining apparatus according to claim 1, wherein
the motor is installed in a railway vehicle and generates a propulsion of the railway vehicle, and
the antenna is disposed adjacent to rails on which the railway vehicle runs.

18. The degradation determining apparatus according to claim 5, wherein
the plurality of motor is installed in a railway vehicle and generates a propulsion of the railway vehicle, and
the plurality of antennas is disposed adjacent to rails on which the railway vehicle runs.

19. The degradation determining apparatus according to claim 1, wherein
the motor is installed in a railway vehicle, and
the degradation determining circuitry determines, based on the reception signal and a history of an operation condition of the motor, whether any degradation occurs in the insulating member, the operation condition including at least one of a running period of a power conversion apparatus that feeds electric power to the motor, a switching frequency of the power conversion apparatus, a rotational speed of the motor, a temperature of the motor, or an occupancy rate of a vehicle body provided with the motor in the railway vehicle.

20. The degradation determining apparatus according to claim 5, wherein
the plurality of motors is installed in a railway vehicle, and
the degradation determining circuitry determines, based on the difference among signal values of the reception signals and a history of an operation condition of the plurality of motors, whether any degradation occurs in the insulating member, the operation condition including at least one of a running period of a power conversion apparatus that feeds electric power to the motor, a switching frequency of the power conversion apparatus, a rotational speed of the motor, a temperature of the motor, or an occupancy rate of a vehicle body provided with the motor in the railway vehicle.

21. A degradation determining method, comprising:
comparing a phase characteristic of a signal intensity of a reception signal obtained by receiving an electromagnetic wave in a microwave frequency band emitted due to partial discharge occurring in an insulating member included in a motor with a phase characteristic pattern associated with a type of degradation in the insulating member; and
determining whether any degradation occurs in the insulating member and identifying the type of the degradation in the insulating member including at least one of a cause of the degradation in the insulating member or a position of the degraded insulating member.
